(19) United States
(12) Patent Application Publication
(10) Pub. No.: US 2007/0155033 A1
(43) Pub. Date: Jul. 5, 2007

(54) Method of manufacturing light emitting diode package

(75) Inventors: Yong Sik Kim, Yongin (KR); Seog Moon Choi, Seoul (KR); Yong Suk Kim, Suwon (KR); Sang Hyun Shin, Hwasung (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/649,914

(22) Filed: Jan. 5, 2007

(30) Foreign Application Priority Data
Jan. 5, 2006 (KR) 10-2006-0001519

(51) Int. Cl. H01L 21/00

(52) U.S. Cl. 438/27; 257/E33.073

(57) ABSTRACT

A method of manufacturing an LED package. The method includes dispensing a transparent resilient resin on an LED package body and overturning an entire structure to form an LED lens integrally provided to the LED package body. This prevents extra processes and costs incurring from forming intermediate layers and obviates degradation in reliability and light extraction efficiency due to additional interfaces.

### CLAIM OF PRIORITY

This application claims the benefit of Korean Patent Application No. 2006-0001519 filed on Jan. 5, 2006, in the Korean Intellectual Property Office, the disclosure of which is incorporated herein by reference.

### BACKGROUND OF THE INVENTION

1. Field of the Invention

The present invention relates to a Light Emitting Diode (LED) package and, more particularly, to a method of manufacturing an LED package in which a transparent resilient resin is dispensed on an LED package body and an entire structure is overturned by an overturning technique to form an LED lens integrally with the LED package body, preventing extra processes and costs incurred from forming intermediate layers, thereby obviating degradation in reliability and light extraction efficiency.

2. Description of the Related Art

In general, a Light Emitting Diode (LED) is a semiconductor device for generating light of various colors in response to application of current. The color of light generated from the LED is determined by the chemical components constituting the semiconductor of the LED. Such an LED has various advantages such as longer lifetime, low power, excellent initial driving characteristics, high vibration resistance and high tolerance for repetitive power switching compared to a filament-based light emitting device. Thus, there has been an increasing demand for the LEDs.

Used as backlights for lighting devices and large-sized Liquid Crystal Displays (LCDs), the LEDs are required to produce high output and thus require a package structure with excellent radiation capacity. Further, in order to emit the generated light to the outside, a package structure with extra high light extraction efficiency is required.

A conventional method of manufacturing an LED package entails separately preparing an LED package body including a substrate part, an LED chip and a transparent encapsulant encapsulating these and a cover for the LED package, i.e., a lens and bonding the package body and the lens. The conventional manufacturing method of the LED package will now be examined with reference to FIG. 1.

FIG. 1(a) illustrates a process of manufacturing the lens of the LED package. That is, a resin 38 is poured into a mold 36 and is taken out once completely cured to form the lens 40.

On the other hand, FIG. 1(b) illustrates a process of forming the LED package body. This entails forming a pair of leads 24 on a substrate or a substrate part 22 having a recess formed in an upper surface thereof, mounting the LED chip 26 on the lead 24 and electrically connecting the LED chip 26 to the lead 24 by wires 28, and filling the recess with a resilient resin such as transparent silicone to form the transparent encapsulant 30. For the transparent encapsulant 30, a transparent resilient resin is used instead of a transparent epoxy because a general transparent epoxy can easily be deformed by the heat from the LED chip 26.

After preparing the LED package body 20 and the LED lens 40 separately as described above, the lens 40 is attached to the LED package body 20 as shown in FIG. 1(c) to complete the LED package 1. Here, the lens 40 is adhered to the LED package body 20 using a transparent adhesive 42.

However, the conventional method of manufacturing the LED package has following drawbacks. First, the LED lens 40 is separately prepared using the mold 36 for fabrication of lens, incurring extra processes and costs.

Furthermore, the transparent adhesive 42 is inserted as an intermediate layer between the LED package body 20 and the lens 40, creating additional interfaces between the resilient resin 30 and the transparent adhesive 42 and between the transparent adhesive 42 and the lens 40. This allows intrusion of moisture and ultraviolet rays through the interfaces, undermining the overall reliability of the package and the light extraction efficiency of the LED chip 26.

### SUMMARY OF THE INVENTION

The present invention has been made to solve the foregoing problems of the prior art and therefore an aspect of the present invention is to provide a method of manufacturing an LED package in which a resilient resin is dispensed on an LED package body and an entire structure is overturned by an overturning technique to form an LED lens integrally with the LED package body, preventing extra manufacturing processes and costs incurring from conventionally forming intermediate layers, thereby obviating degradation in reliability and light extraction efficiency due to additional interfaces.

According to an aspect of the invention, the invention provides a manufacturing method of a Light Emitting Diode (LED) package. The method includes:

forming a lead on a substrate part having a recess formed in an upper surface thereof, mounting an LED chip on the lead and electrically connecting the LED chip to the lead, and filling a transparent resilient resin in the recess to prepare an LED package body;

dispensing a transparent resin on the package body in a hemispheric shape; and

overturning the structure obtained from the dispensing step and curing the hemispheric transparent resin to form a lens integrally provided to the package body.

According to the method of the present invention, the curing step includes placing the structure obtained from the dispensing step in a curing chamber and curing the transparent resin with the internal pressure lower than the atmospheric pressure. At this time, the pressure is lowered by 0.03 to 0.09 Mpa from the atmospheric pressure.

According to the method of the present invention, the transparent resin adopts a resilient resin.

According to the method of the present invention, the transparent resin adopts a material the same as that of the resilient resin filled in the LED package body.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic view illustrating a manufacturing process of an LED package according to the prior art;

FIG. 2 is a schematic view illustrating a manufacturing process of an LED package according to the present invention;

FIG. 3 is a view illustrating the characteristics of the overturning technique according to the present invention; and

FIG. 4 is a view illustrating a change in a sag according to a change in the pressure.

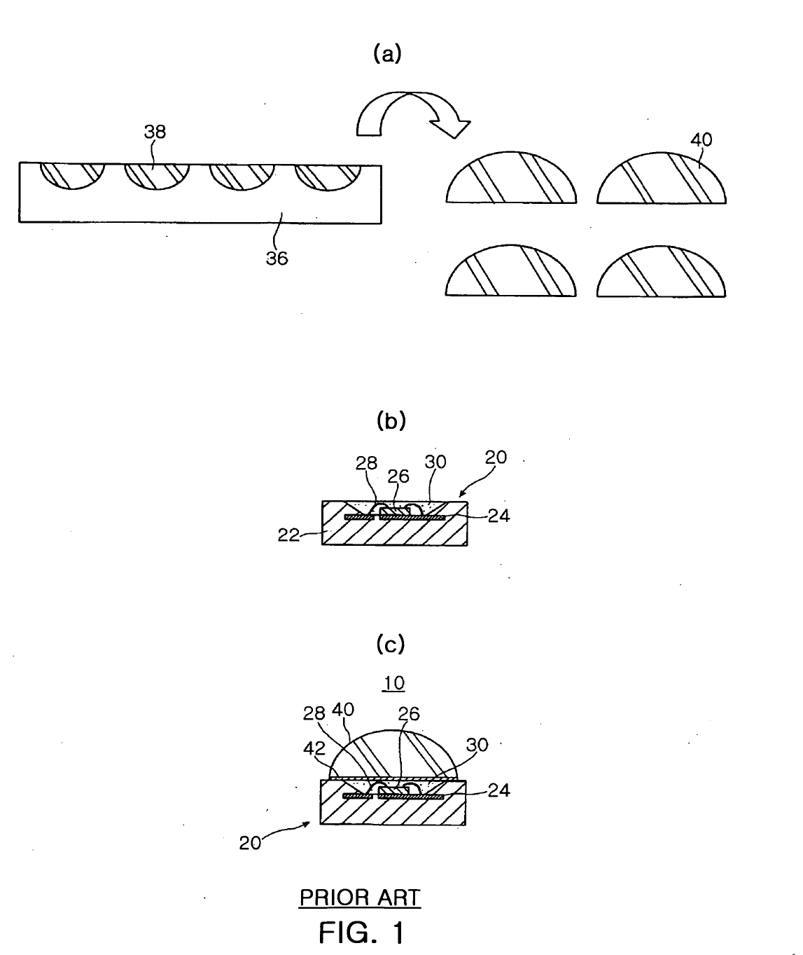

### DETAILED DESCRIPTION OF THE PREFERRED EMBODIMENT

Exemplary embodiments of the present invention will now be described in detail with reference to the accompanying drawings.

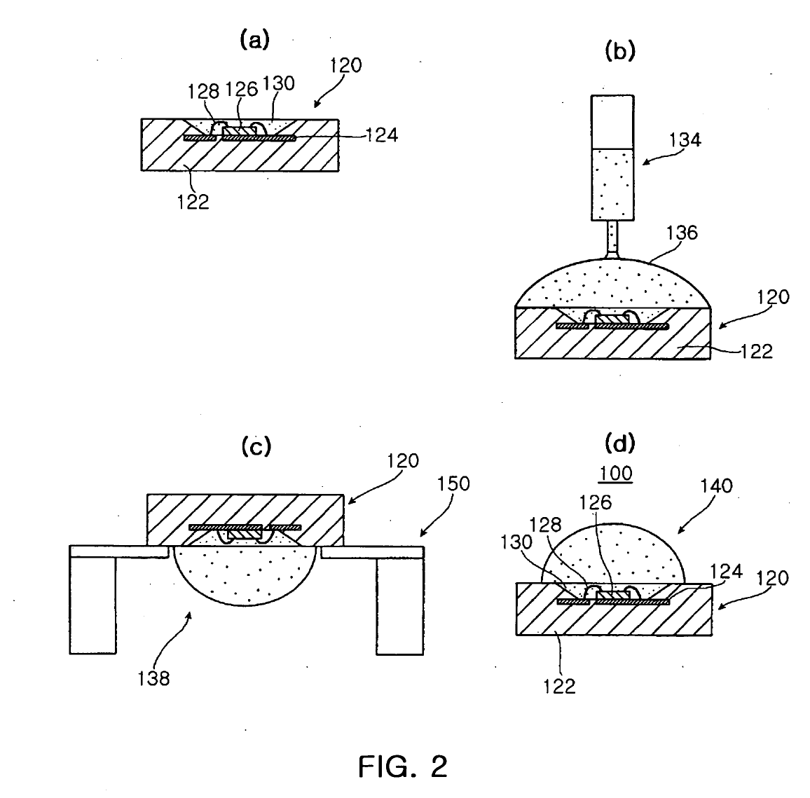

FIG. 2 is a schematic view illustrating a manufacturing process of an LED package according to the present invention.

First, FIG. 2(a) illustrates a step of forming the LED package body of the LED package according to the present invention. To form the LED package body 120, a pair of leads 124 are formed on a substrate or a substrate part 122 having a recess formed in an upper surface thereof, an LED chip 126 is mounted on the lead 124 and electrically connected to the lead 124 by wires 128, and a resilient resin such as transparent silicone is filled in the recess to form a transparent encapsulant 130. Here, the LED chip 126 can also be connected to the lead 124 by a solder bump (not shown) instead of the wires 128.

In this case, a transparent resilient resin is used for the resilient encapsulant 130 instead of a general transparent epoxy. This is because a general transparent epoxy can easily be deformed by the heat generated from the LED chip 126.

On the other hand, the resilient resin is rarely affected by changes due to single-wavelength light, such as yellowing, and has a high refractive index, thus having superior optical characteristics. In addition, unlike epoxy, it maintains a gel or elastomer state even after cured, thereby more stably protecting the LED chip 126 from thermal stress, vibrations and external impacts. Such a resilient resin includes a gel-type resin such as silicone.

Subsequently, as shown in FIG. 2(b), a transparent resin 136 is dispensed with precision by dotting on the LED package body 120 using a syringe 134.

The dispensing amount of the transparent resin 136 varies according to the height of the lens, i.e., the sag. For example, preferably, 5 mg is appropriate for a sag of 1.2 mm, 7 mg for a sag of 1.5 mm, 10 mg for a sag of 2 mm and 13 mg for a sag of 2.5 mm. Of course, these sags are values measured at the atmospheric pressure and given the same amount of the resin, the actual sag obtained increases with lower pressure.

When the transparent resin 136 is dispensed on the LED package body 120 as described above, the obtained structure is overturned and placed over a support 150 such as a jig to cure the hemispheric transparent resin 138 in a curing chamber (not shown) as depicted in FIG. 2(c). After overturned, the transparent resin 136 is increased in height from the state depicted in FIG. 2(b), forming a hemispheric shape.

Through this curing process, the hemispheric transparent resin 138 is cured. Through such a process, the hemispheric transparent resin 138 is cured to form a hemispheric lens 138 integrally provided to the LED package body 120. As a result, an LED package 100 as shown in FIG. 2(d) is obtained.

In the process of manufacturing the LED package 100, it is preferable that the transparent resin 136 dispensed on the LED package body 120 is selected from the same material as the resilient encapsulant 130 previously filled (at least partially) and cured in the LED package body 120. When formed with the same materials, the resilient encapsulant 130 and the transparent resin 136 have a greater adhesiveness and the lens 140 is more stably maintained on the package body 120. Of course, even if the materials are not the same, materials that easily bond with each other may ensure stable holding of the lens 140 to the LED package body 120.

Using a resilient resin for the transparent resin 136 has following advantages. That is, in the case of a high output LED, the heat generated from the LED chip 126 can be transferred via the resilient encapsulant 130 to the transparent resin 136. In this case, if made of epoxy-based resin vulnerable to heat, the transparent resin 136 can be damaged by the heat. However, if made of the resilient resin such as transparent silicone, the transparent resin 136 is less likely to be deformed by the heat, which makes it advantageous to maintain optical characteristics.

The curing conditions of the transparent resin can vary according to the desired sag of the lens, and a representative example is shown in Table 1. Of course, here, the values of the sag were measured at the atmospheric pressure.

TABLE 1

| Amount of | Curing | Curing | |
|---|---|---|---|
| resin (mg) | time (minutes) | temperature (° C.) | Sag (mm) |
| 5 | 30 | 150 | 1.2 |
| 7 | 30 | 150 | 1.5 |
| 10 | 60 | 150 | 2.0 |
| 13 | 80 | 150 | 2.5 |

In the meantime, the pressure inside the curing chamber can be adjusted according to the amount and viscosity of the hemispheric transparent resin 138 to regulate the curvature of the hemispheric transparent resin 138, thereby controlling the height of the lens or the sag.

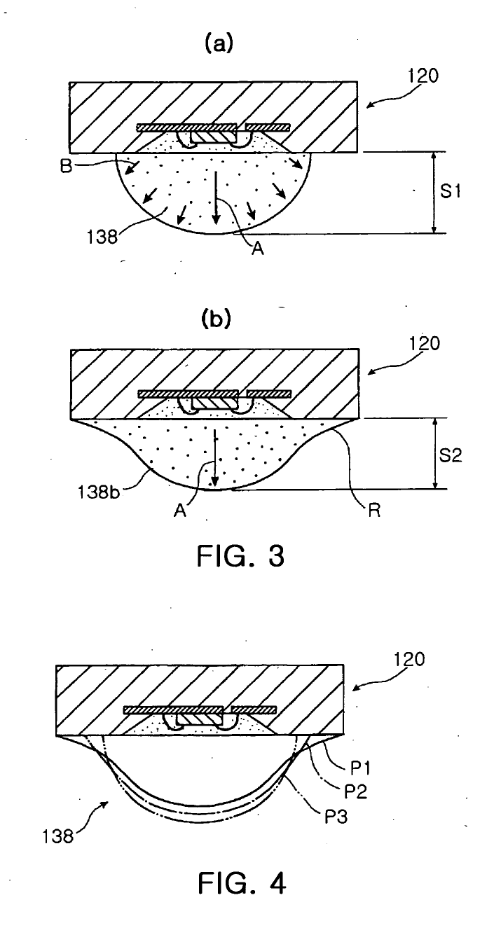

This will be explained with reference to FIG. 3. In FIG. 3, (a) illustrates the case in which the pressure in the curing chamber is adjusted lower than the atmospheric pressure while the structure is overturned and (b) illustrates the case in which the pressure in the curing chamber is not lowered but maintained at the atmospheric pressure.

First, if the curing chamber is maintained at the atmospheric pressure, the transparent resin 138 partially hangs down in the direction denoted by the arrow A by the gravity, and forms an indentation R at the portion thereof that comes in contact with the LED package body 120. This hinders forming the transparent resin 138 in a regulated curvature.

On the other hand, as shown in FIG. 3(a), if the pressure in the curing chamber is lowered, the pressure B inside the transparent resin becomes greater than the outside, and thereby the transparent resin 138 hangs down by the gravity working in the direction denoted by the arrow A and under the influence of the inner pressure B. Therefore, the height of the transparent resin 138a, i.e., the sag S1 of the final lens in FIG. 3(a) is greater than the height of the transparent resin 138b, i.e., the sag S2 of the final lens in FIG. 3(b).

Therefore, it can be seen from the above observation that the sag of the lens increases with lower pressure. This is clearer with reference to FIG. 4. In FIG. 4, P1 represents the sag at the atmospheric pressure, and P2 and P3 represent the sags at pressure levels inside the curing chamber adjusted lower than the atmospheric pressure, and the relationship can be represented by P1>P2>P3.

As described above, lowering the pressure inside the curing chamber increases the sag of the final lens and facilitates forming the lens in a hemispheric shape.

The hemispheric transparent resin 138 is cured in the above conditions results in obtaining a hemispheric lens 140 as shown in FIG. 2(d).

Such conditions for lowering pressure inside the curing chamber are determined according to the amount and viscosity of the dispensed transparent resin 136. For example, in case of curing 5 mg of transparent resin having a viscosity of 3000 mPa·s at 150° C. by the overturning technique, the height of the lens or the sag according to the pressure decrease is as shown in Table 2.

TABLE 2

| Pressure decrease(MPa) | Lens sag(mm) |
|---|---|
| 0(atmospheric pressure) | 1.2 |
| 0.03 | 1.2 |
| 0.04 | 1.7 |
| 0.05 | 2.2 |
| 0.06 | 2.2 |
| 0.07 | 2.7 |
| 0.08 | 3.2 |
| 0.09 | 4.2 |

Therefore, the method according to the present invention as described above prevents extra processes and costs incurring from forming intermediate layers and degradation in reliability and light extraction efficiency due to additional interfaces. In addition, cured by the overturning technique with the pressure lowered, even a resin with great flowability can be cured into a lens without forming bubbles or collapsing while maintaining a hemispheric shape.

Therefore, according to the method of the present invention as described above, the dispensing amount of the transparent resin is adjusted according to the desired sag of the lens and the pressure is lowered inside the curing chamber according to the dispensed amount and viscosity of the transparent resin, thereby obtaining a hemispheric lens having a predetermined curvature.

According to the present invention as set forth above, a transparent resilient resin is dispensed on an LED package body and an entire structure is overturned by an overturning technique with the pressure lowered, thereby obtaining an LED package with an LED lens integrated with the LED package body. This precludes extra processes and costs incurring from forming intermediate layers and prevents degradation in reliability and light extraction efficiency due to additional interfaces. Furthermore, using the overturning technique, even a resin with great flowability can be cured into a lens without forming bubbles or collapsing while maintaining a hemispheric shape.

While the present invention has been shown and described in connection with the exemplary embodiments, it will be apparent to those skilled in the art that modifications and variations can be made without departing from the spirit and scope of the invention as defined by the appended claims.

What is claimed is:

1. A manufacturing method of a Light Emitting Diode (LED) package comprising:
forming a lead on a substrate part having a recess formed in an upper surface thereof, mounting an LED chip on the lead and electrically connecting the LED chip to the lead, and filling a transparent resilient resin in the recess to prepare an LED package body;
dispensing a transparent resin on the package body in a hemispheric shape; and
overturning the structure obtained from the dispensing step and curing the hemispheric transparent resin to form a lens integrally provided to the package body.

2. The method according to claim 1, wherein the curing step comprises placing the structure obtained from the dispensing step in a curing chamber and curing the transparent resin with the internal pressure lower than the atmospheric pressure.

3. The method according to claim 2, wherein the pressure is lowered by 0.03 to 0.09 Mpa from the atmospheric pressure.

4. The method according to claim 1, wherein the transparent resin comprises a resilient resin.

5. The method according to claim 1, wherein the transparent resin comprises a material the same as that of the resilient resin filled in the LED package body.
